(19) United States
(12) Patent Application Publication
(10) Pub. No.: US 2022/0090863 A1
(43) Pub. Date: Mar. 24, 2022

(54) Hot Air Flow Direction Control Mechanism of Base Board Baking Machine

(71) Applicant: Tung-Min Lee, Kaohsiung City (TW)

(72) Inventor: Tung-Min Lee, Kaohsiung City (TW)

(21) Appl. No.: 17/543,960

(22) Filed: Dec. 7, 2021

Related U.S. Application Data
(63) Continuation-in-part of application No. 16/170,091, filed on Oct. 25, 2018, now abandoned.

(51) Int. Cl. F27B 17/00; F27D 7/04

(52) U.S. Cl. CPC F27B 17/0083; F27D 2007/045; F27D 7/04

(57) ABSTRACT

A hot air flow direction control mechanism of a base board baking machine includes a stand, a controller, a housing, a hot air device, an air suction unit, and a top cover. Thus, the hot air device blows the hot air into the housing, and the air suction unit sucks the hot air so that the hot air is circulated evenly in the housing and around the periphery of the housing.

### CROSS-REFERENCES TO RELATED APPLICATIONS

The present invention is a continuation-in-part (C.I.P.) application of the co-pending U.S. Ser. No. 16/170,091, filed on Oct. 25, 2018.

### BACKGROUND OF THE INVENTION

### 1. Field of the Invention

The present invention relates to a base board baking machine and, more particularly, to a hot air flow direction control mechanism of a base board baking machine.

### 2. Description of the Related Art

A liquid crystal display, such as the TFT-LCD, includes two glass base boards that need to be baked. A conventional base board baking machine in accordance with the prior art shown in FIG. 10 is used to bake a base board 30, and comprises a housing 3 for receiving a hot plate 31 and a heater 311. The hot plate 31 is located above the heater 311. The base board 30 is placed in the housing 3 and located above the hot plate 31. The base board 30 has two edges 301. In operation, the hot plate 31 is heated by the heater 311 so as to heat the base board 30. However, the hot plate 31 cannot keep the base board 30 at a constant temperature during the baking process, thereby decreasing the baking effect of the base board 30, and thereby decreasing the production quality of the base board 30. In addition, the two edges 301 of the base board 30 are easily raised and spaced from the hot plate 31, so that the two edges 301 of the base board 30 are not heated by the hot plate 31, thereby greatly decreasing the quality of the base board 30.

### BRIEF SUMMARY OF THE INVENTION

In accordance with one embodiment of the present invention, there is provided a hot air flow direction control mechanism of a base board baking machine, comprising a stand, a controller mounted on a side of the stand, a housing mounted on a top of the stand, a hot air device mounted on the stand and connected to the housing, an air suction unit mounted on the stand and connected to the housing, and a top cover pivotally mounted on and closing the housing. The hot air device includes multiple air outlets, a power supply, a fan, a heater, and multiple air conduits. The air outlets are arranged in the housing. The fan is operated to produce an air current which is heated by the heater to form a hot air which passes through the air conduits and is delivered through the air outlets into the housing so that the hot air is circulated in the housing. The air suction unit includes multiple air suction ports, at least one upper pipeline, at least one side pipeline, an air collection box, an air exhaust pipe, and an air blower. The air suction ports are mounted on a peripheral wall of the housing and the top cover. The hot air in the housing is drawn by operation of the air blower so that the hot air in the housing is delivered through the air suction ports into the at least one upper pipeline and the at least one side pipeline, delivered through the air collection box, the air exhaust pipe, and the air blower, and is drained outward from the air blower.

According to the primary advantage of the present invention, the hot air device blows the hot air into the housing, and the air suction unit sucks the hot air so that the hot air is circulated evenly in the housing and around the periphery of the housing.

Further benefits and advantages of the present invention will become apparent after a careful reading of the detailed description with appropriate reference to the accompanying drawings.

### BRIEF DESCRIPTION OF THE SEVERAL VIEWS OF THE DRAWING(S)

FIG. 1 is a perspective view of a hot air flow direction control mechanism of a base board baking machine in accordance with the preferred embodiment of the present invention.

FIG. 2 is a perspective view showing a hot air device of the hot air flow direction control mechanism in accordance with the preferred embodiment of the present invention.

FIG. 3 is a schematic view showing an air suction unit of the hot air flow direction control mechanism in accordance with the preferred embodiment of the present invention.

FIG. 4 is another schematic view showing the air suction unit of the hot air flow direction control mechanism in accordance with the preferred embodiment of the present invention.

FIG. 5 is a schematic operational view showing flow directions of the hot air of the hot air flow direction control mechanism in accordance with the preferred embodiment of the present invention.

FIG. 6 is a schematic cross-sectional view showing flow directions of the hot air of the hot air flow direction control mechanism in accordance with the preferred embodiment of the present invention.

FIG. 7 is a perspective view of a hot air flow direction control mechanism of a base board baking machine in accordance with another preferred embodiment of the present invention.

FIG. 8 is a schematic cross-sectional view showing flow directions of the hot air of the hot air flow direction control mechanism as shown in FIG. 7.

FIG. 9 is a perspective view of a hot air flow direction control mechanism of a base board baking machine in accordance with a further preferred embodiment of the present invention.

FIG. 10 is a cross-sectional view of a conventional base board baking machine in accordance with the prior art.

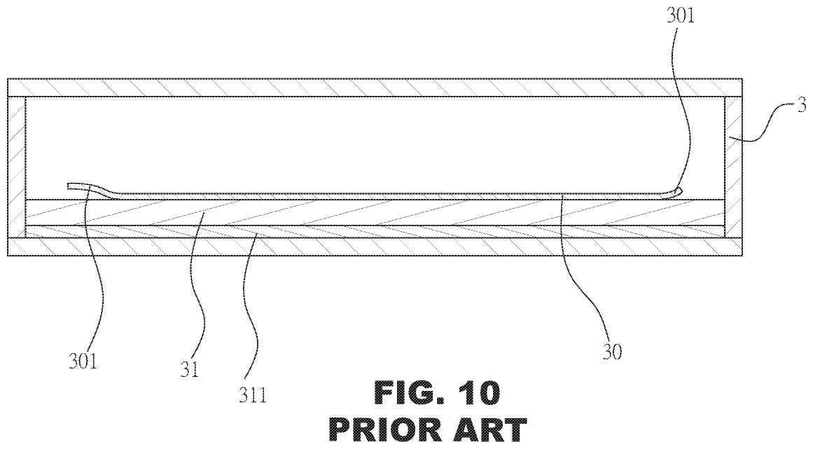

### DETAILED DESCRIPTION OF THE INVENTION

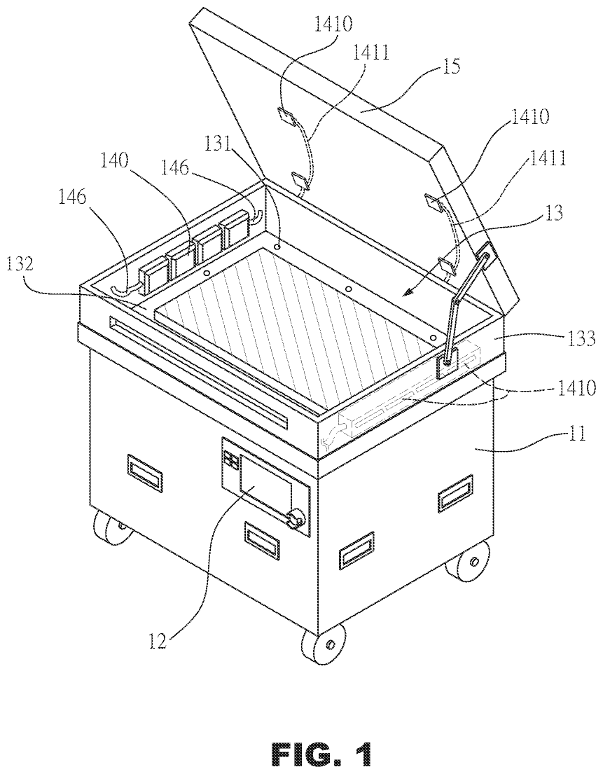

Referring to the drawings and initially to FIGS. 1-6, a hot air flow direction control mechanism of a base board baking machine in accordance with the preferred embodiment of the present invention comprises a stand 11, a controller 12 mounted on a side of the stand 11, a housing 13 mounted on a top of the stand 11, a hot air device 14 mounted on the stand 11 and connected to the housing 13, an air suction unit 141 mounted on the stand 11 and connected to the housing 13, and a top cover 15 pivotally mounted on and closing the housing 13.

The hot air device 14 includes multiple air outlets 140, a power supply 143, a fan 144, a heater 145, and multiple air conduits 146.

The air outlets 140 are arranged in the housing 13. The power supply 143 is electrically connected with the fan 144 and supplies an electric power to the fan 144. The fan 144 is connected to the heater 145. The heater 145 is connected to the air conduits 146. The air conduits 146 extends into the housing 13 and are connected to the air outlets 140. The fan 144 is operated to produce an air current which is heated by the heater 145 to form a hot air which passes through the air conduits 146 and is delivered through the air outlets 140 into the housing 13 so that the hot air is circulated in the housing 13.

The air suction unit 141 includes multiple air suction ports 1410, at least one upper pipeline 1411, at least one side pipeline 1412, an air collection box 1414, an air exhaust pipe 1415, an air blower 1413, and an air outlet 1416.

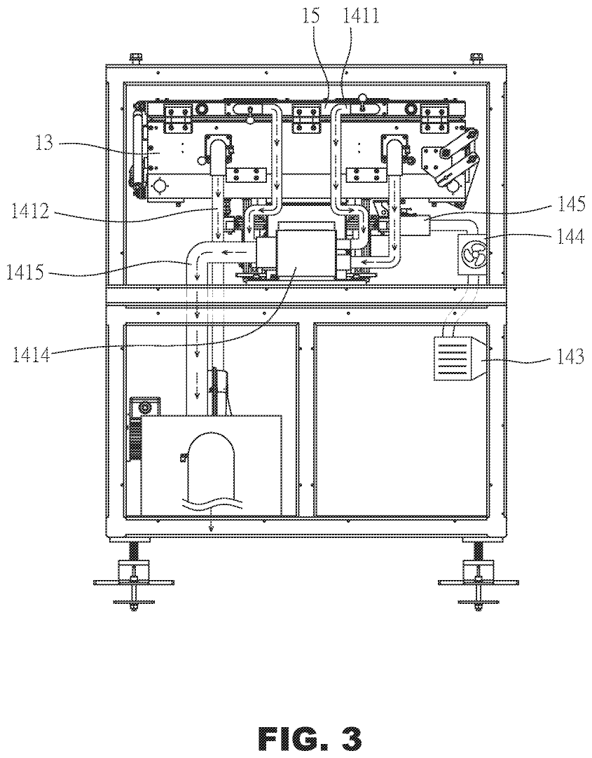

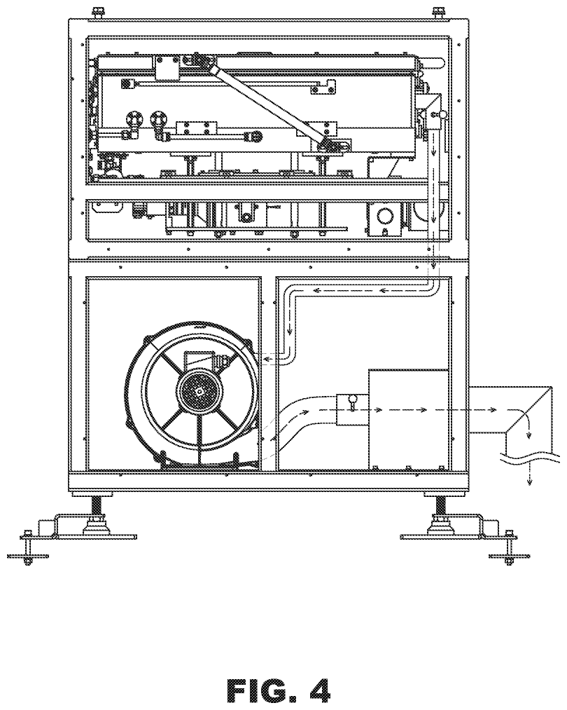

The air suction ports 1410 are mounted on a peripheral wall 133 of the housing 13 and the top cover 15. The at least one upper pipeline 1411 is mounted on a side of the top cover 15 and connected to the air suction ports 1410 so that the hot air is drained outward from the top cover 15. The at least one side pipeline 1412 is mounted on a side of the housing 13 and connected to the air suction ports 1410 so that the hot air is drained outward from the housing 13. The air collection box 1414 is connected to the at least one upper pipeline 1411 and the at least one side pipeline 1412. The air exhaust pipe 1415 is connected to the air collection box 1414. The air blower 1413 is connected to the air exhaust pipe 1415. The air outlet 1416 is connected to the air blower 1413. The hot air in the housing 13 is drawn by a suction force produced by operation of the air blower 1413 so that the hot air in the housing 13 is delivered through the air suction ports 1410 into the at least one upper pipeline 1411 and the at least one side pipeline 1412, then delivered through the air collection box 1414, the air exhaust pipe 1415, and the air blower 1413, and is finally drained outward from the air outlet 1416 as shown in FIGS. 3 and 4.

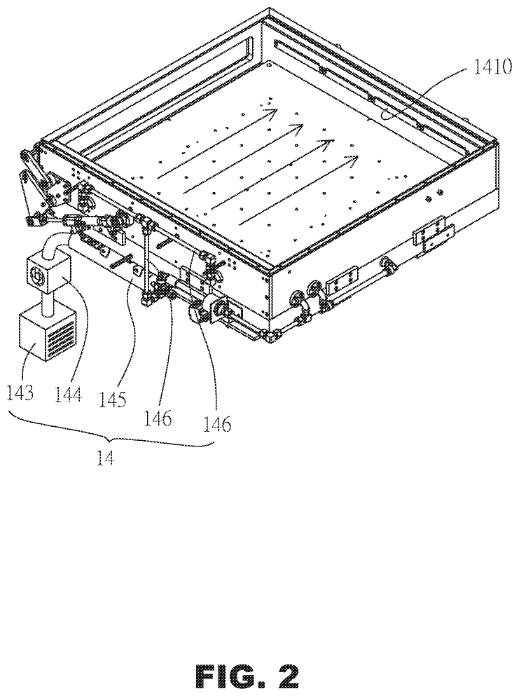

In practice, the hot air device 14 blows and emits the hot air into the housing 13, and the air suction unit 141 sucks the hot air so that the hot air flows in the housing 13 from left to right as shown in FIG. 2, and the hot air is circulated evenly in the housing 13 and around the periphery of the housing 13.

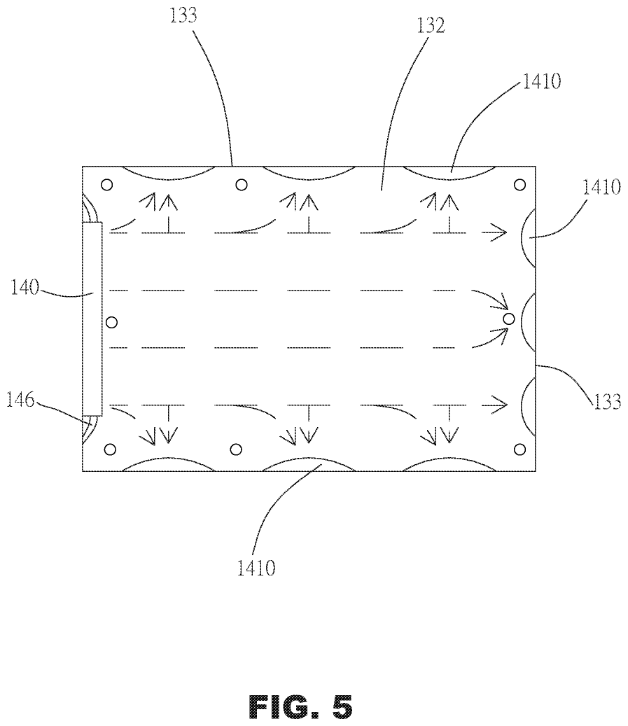

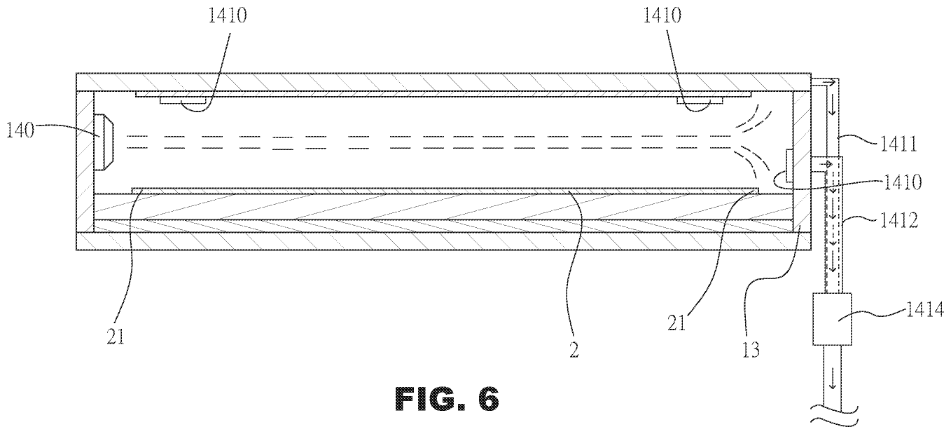

Thus, the hot air device 14 supplies and delivers the hot air, and the air suction unit 141 sucks and drains the hot air, such that the hot air device 14 and the air suction unit 141 cooperate to form an air convection of the hot air as shown in FIGS. 5 and 6, to accelerate and expand flow of the hot air, such that the hot air is fully circulated in the housing 13. The controller 12 regulates and sets the hot air device 14 at a constant timing, temperature, and flow rate. The controller 12 also turns on/off the air suction unit 141. A plurality of temperature sensors 131 are mounted in the housing 13 to control the temperature and regulate the flow rate of the hot air in the housing 13.

Referring to FIGS. 5 and 6 with reference to FIGS. 1-4, a base board (or base plate or substrate) 2 is mounted in the housing 13 and placed on a bottom plate 132 of the housing 13. The base board 2 has two ends 21.

In practice, the air suction ports 1410 are mounted on the peripheral wall 133 of the housing 13. Thus, when the hot air device 14 delivers the hot air into the housing 13, the air suction unit 141 sucks the hot air by operation of the air blower 1413 so that the hot air forms an air convection in the housing 13, and extends to corners of the housing 13 that have a lower temperature so as to heat the base board 2 completely, such that the two ends 21 of the base board 2 are also heated as shown in FIG. 6.

It is appreciated that the hot air flow direction control mechanism primarily includes the hot air device 14 and the air suction unit 141. In such a manner, the hot air is blown from the hot air device 14, and is sucked by the air suction unit 141, such that the hot air is delivered to the periphery of the housing 13 and is fully circulated in the housing 13. Thus, the two ends 21 of the base board 2 are heated evenly by the hot air, such that the base board 2 is heated fully and evenly.

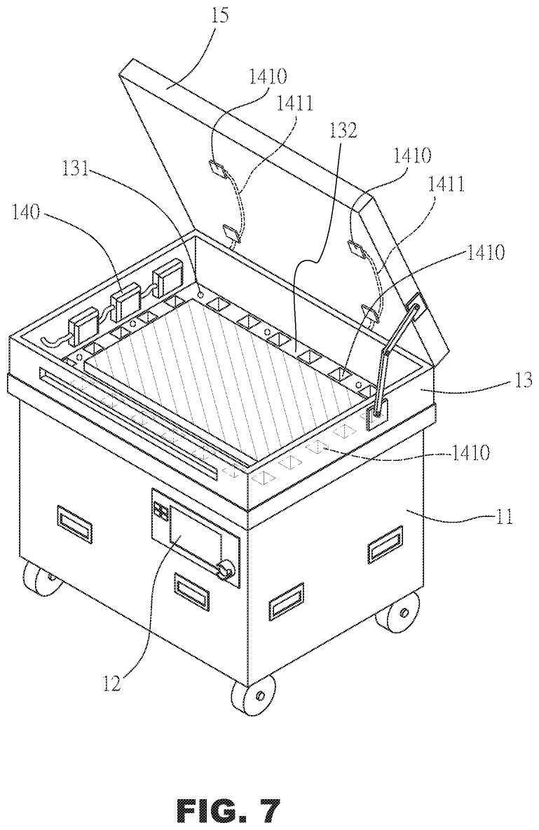

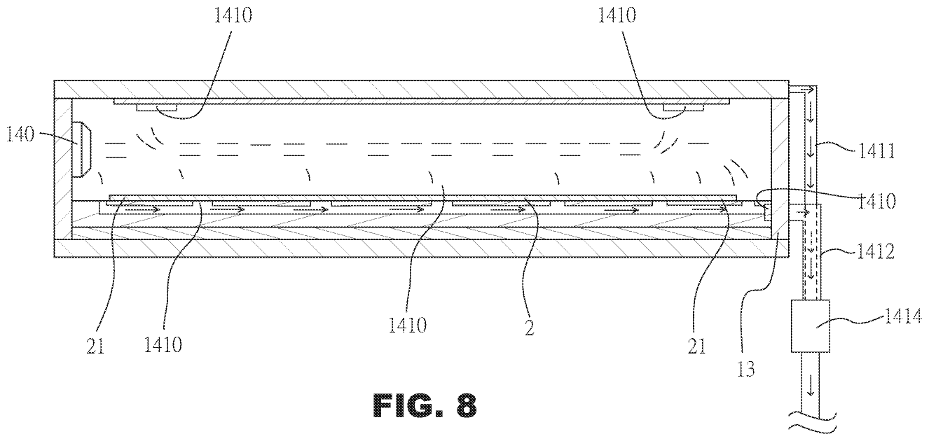

Referring to FIGS. 7 and 8, the air suction ports 1410 of the air suction unit 141 are mounted on four sides of the bottom plate 132 of the housing 13 to enhance the heat convection effect. The hot air in the housing 13 is delivered through the air suction ports 1410 into the at least one side pipeline 1412, then delivered through the air collection box 1414, the air exhaust pipe 1415, and the air blower 1413, and is finally drained outward from the air outlet 1416 as shown in FIGS. 3 and 4.

In such a manner, after the hot air is blown outward from the hot air device 14, the air suction ports 1410 of the air suction unit 141 are adjusted to control the flow direction of the hot air, such that the hot air from the hot air device 14 is blown and moved toward the periphery of the housing 13. Thus, the hot air is distributed evenly in the housing 13 and expanded to reach the corners of the housing 13 at a lower temperature so as to heat the base board 2 completely, such that the two ends 21 of the base board 2 are also heated as shown in FIG. 8.

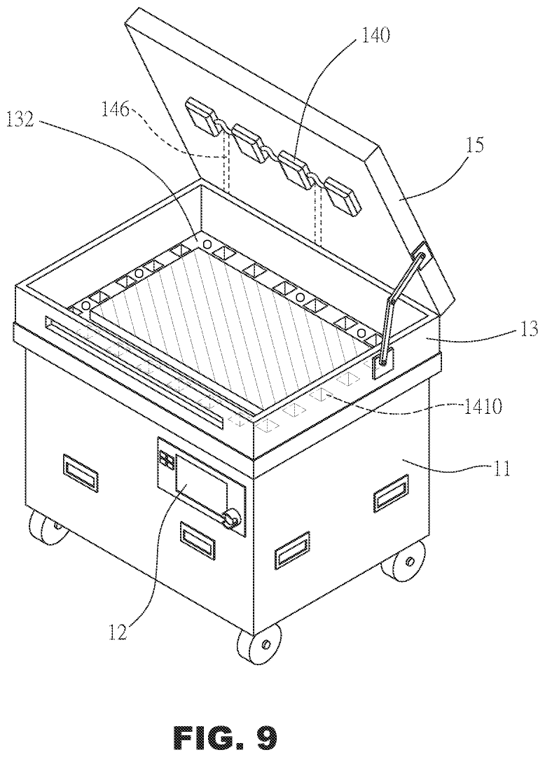

Referring to FIG. 9, the air outlets 140 of the hot air device 14 are mounted on an inside of the top cover 15 to accelerate a full flow of the hot air and to exactly control the direction of the hot air. At the same time, the air suction ports 1410 of the air suction unit 141 are mounted on four sides of the bottom plate 132 of the housing 13. In addition, the air suction ports 1410 of the air suction unit 141 are turned on or off selectively. In such a manner, when the top cover 15 closes the housing 13, the hot air from the air outlets 140 of the hot air device 14 is blown downward, and when the air suction unit 141 is started, the hot air is blown and moved toward the air suction ports 1410 of the air suction unit 141. Thus, when the base board 2 is baked, the temperature at the periphery of the bottom plate 132 is detected, and the air suction ports 1410 of the air suction unit 141 near the periphery of the bottom plate 132 are started, to efficiently enhance the heat convection effect in the housing 13, and to increase the temperature at the periphery of the housing 13, so as to achieve a full heat diffusion in the housing 13.

It is appreciated that, the hot air device 14 is mounted on the inside of the top cover 15, such that the hot air device 14 directly blows the hot air toward the base board 2. In addition, the air suction ports 1410 of the air suction unit 141 are turned on or off according to the preset temperature, such that the hot air compensates the temperature of the two ends 21 of the base board 2, and accelerates flow and diffusion of the hot air.

Further referring to FIG. 9, the hot air is blown from the hot air device 14 to heat the base board 2 gradually, and the air suction ports 1410 of the air suction unit 141 surrounding the bottom plate 132 suck and drain the hot air, to produce a heat convection, and to control the flow direction of the hot air. Thus, the heat from the hot air device 14 reaches the corners of the housing 13 such that the whole region of the housing 13 is kept at a constant temperature, and the base board 2 is heated evenly and completely, so as to enhance the quality of the base board 2.

Accordingly, the hot air device 14 and the air suction unit 141 produce a heat convection to achieve a fully developed heating effect, such that the hot air is fully circulated in the housing 13, and the base board 2 is heated evenly and completely, thereby enhancing the quality of the base board 2. In addition, the hot air device 14 blows the hot air, and the air suction unit 141 sucks and drains the hot air, to control the flow direction of the hot air during the process of air delivery and air suction, such that the hot air is delivered to all of the corners of the housing 13, so as to heat the two ends 21 of the base board 2 evenly and exactly.

Although the invention has been explained in relation to its preferred embodiment(s) as mentioned above, it is to be understood that many other possible modifications and variations can be made without departing from the scope of the present invention. It is, therefore, contemplated that the appended claim or claims will cover such modifications and variations that fall within the scope of the invention.

1. A hot air flow direction control mechanism of a base board baking machine, comprising:
a stand;
a controller mounted on a side of the stand;
a housing mounted on a top of the stand;
a hot air device mounted on the stand and connected to the housing;
an air suction unit mounted on the stand and connected to the housing; and
a top cover pivotally mounted on and closing the housing;
wherein:
the hot air device includes multiple air outlets, a power supply, a fan, a heater, and multiple air conduits;
the air outlets are arranged in the housing;
the fan is operated to produce an air current which is heated by the heater to form a hot air which passes through the air conduits and is delivered through the air outlets into the housing so that the hot air is circulated in the housing;
the air suction unit includes multiple air suction ports, at least one upper pipeline, at least one side pipeline, an air collection box, an air exhaust pipe, and an air blower;
the air suction ports are mounted on a peripheral wall of the housing and the top cover; and
the hot air in the housing is drawn by operation of the air blower so that the hot air in the housing is delivered through the air suction ports into the at least one upper pipeline and the at least one side pipeline, delivered through the air collection box, the air exhaust pipe, and the air blower, and is drained outward from the air blower.

2. The hot air flow direction control mechanism of a base board baking machine of claim 1, wherein the air suction ports of the air suction unit are mounted on four sides of the bottom plate of the housing.

3. The hot air flow direction control mechanism of a base board baking machine of claim 1, wherein the air outlets of the hot air device are mounted on an inside of the top cover.

4. The hot air flow direction control mechanism of a base board baking machine of claim 1, further comprising:
a plurality of temperature sensors mounted in the housing to control a temperature and regulate a flow rate of the hot air in the housing.

5. The hot air flow direction control mechanism of a base board baking machine of claim 1, wherein the fan is connected to the heater, the heater is connected to the air conduits, and the air conduits extends into the housing and are connected to the air outlets.

6. The hot air flow direction control mechanism of a base board baking machine of claim 1, wherein:
the at least one upper pipeline is mounted on a side of the top cover and connected to the air suction ports so that the hot air is drained outward from the top cover;
the at least one side pipeline is mounted on a side of the housing and connected to the air suction ports so that the hot air is drained outward from the housing;
the air collection box is connected to the at least one upper pipeline and the at least one side pipeline;
the air exhaust pipe is connected to the air collection box; and
the air blower is connected to the air exhaust pipe.

7. The hot air flow direction control mechanism of a base board baking machine of claim 1, wherein the hot air device blows the hot air into the housing, and the air suction unit sucks the hot air so that the hot air flows in the housing from left to right, and the hot air is circulated evenly in the housing and around a periphery of the housing.
